(19) United States
(12) Patent Application Publication
(10) Pub. No.: US 2011/0101448 A1
(43) Pub. Date: May 5, 2011

(54) VERTICAL TRANSISTOR AND MANUFACTURING METHOD THEREOF

(75) Inventors: HSIN-HUEI CHEN, MIAOLI COUNTY (TW); CHUNG-YUAN LEE, TAOYUAN COUNTY (TW)

(73) Assignee: INOTERA MEMORIES, INC., TAOYUAN COUNTY (TW)

(21) Appl. No.: 12/711,438

(22) Filed: Feb. 24, 2010

(30) Foreign Application Priority Data
Oct. 30, 2009 (TW) 98136881

(51) Int. Cl. H01L 29/78; H01L 21/336

(52) U.S. Cl. 257/329; 438/268; 257/E29.262; 257/E21.41

(57) ABSTRACT

A vertical transistor includes: a substrate, a bottom-oxide layer, an epitaxial silicon layer, an insulating oxide layer, two gate-oxide films and a gate-stacked layer. The bottom-oxide layer is disposed on the substrate, and the bottom-oxide layer has a gate recess concavely formed thereof. The substrate has a first doped area in an upper part corresponding to the gate recess. The epitaxial silicon layer is formed on the gate recess, and the epitaxial silicon layer has a second doped area in an upper part. The insulating oxide layer is disposed on the epitaxial silicon layer. The gate-oxide films are respectively formed on two opposite sides of the epitaxial silicon layer. The gate-stacked layer is formed on the two gate-oxide layers and the bottom-oxide layer. Whereby, the lateral area of transistor is reduced, and the integration and the performance of the device are improved.

### BACKGROUND OF THE INVENTION

1. Field of the Invention

The present invention relates to a transistor and its manufacturing method; especially, the present invention relates to a vertical transistor and its manufacturing method.

2. Description of Related Art

As electronics technology develops and improves, manufacturing processes continue placing pressure upon, and necessarily driving, electronic products to evolve toward the smaller size and lighter weight as well as further driving DRAM (dynamic random access memory) designs toward high integration and high density. Please refer to FIG. 1; a traditional planar transistor of DRAM includes a substrate 1a and a gate 2a. The gate 2a is formed on the substrate 1a. Furthermore, a source 11a and a drain 12a are respectively formed in the substrate 1a on two sides of the gate 2a. The gate 2a has an oxide 21a and two spacers 22a.

However, due to the planar arrangement of the source 11a, the drain 12a and the gate 2a, the transistor occupies significant area of the substrate 1a. In light of this, integration of the semiconductor is difficult to increase. On the other hand, it is necessary to shrink the size of transistor for increasing the integration of the semiconductor and for improving the density and the performance of the semiconductor devices. The performance of the traditional planar transistor is hard to achieve while it is used on sub-50 nm DRAM technology.

Consequently, with regard to the resolution of defects illustrated hereinbefore, the inventors of the present invention propose a reasonably designed solution for effectively eliminating such disadvantages.

### SUMMARY OF THE INVENTION

The objective of the present invention is to provide a vertical transistor characterized by: reduced lateral area of the transistor, improved device integration and performance, and provision of a manufacturing method of the vertical transistor.

To achieve the objective described above, the present invention discloses a vertical transistor, comprising: a substrate; a bottom-oxide layer disposed on the substrate, the bottom-oxide layer having a gate recess concavely formed in a generally concave manner therein, the substrate having at least one first doped area in an upper part thereof corresponding to the gate recess; an epitaxial silicon layer formed on the gate recess, the epitaxial silicon layer having at least one second doped area in an upper part thereof; an insulating oxide layer disposed on the epitaxial silicon layer; two gate-oxide films, respectively formed on two opposite sides of the epitaxial silicon layer; and a gate-stacked layer formed on the two gate-oxide layers and the bottom-oxide layer.

The present invention further discloses a manufacturing method of the vertical transistor. The manufacturing method includes the step of: providing a substrate; forming a bottom-oxide layer on the substrate; etching a part of the bottom-oxide layer via lithography process to form a gate recess on the bottom-oxide layer; forming at least one first doped area in an upper part of the substrate corresponding to the gate recess; depositing an epitaxial silicon layer on the gate recess and the bottom-oxide layer; forming an insulating oxide layer on the epitaxial silicon layer, and then forming an insulating nitride layer on the insulating oxide layer; removing part of the insulating nitride layer, part of insulating oxide layer and part of the epitaxial silicon layer by lithography process; forming at least one second doped area in a upper part of the epitaxial silicon layer; forming a gate-oxide film on two opposite sides of the epitaxial silicon layer, and forming a gate-stacked layer on the insulating oxide layer, the gate-oxide film and bottom-oxide layer; and etching part of the gate-stacked layer by lithography process.

The present invention provides beneficial effects, including:

1. the source, the gate/transistor body, and the drain of the transistor are vertically constructed so that the lateral area of the transistor may be reduced, thereby, integration and performance of the semiconductor is improved;

2. by etching the gate-stacked layer partially according to the final need or function, the capacitor can be selectively disposed on one side of the gate-stacked layer, on nearby sides of the gate-stacked layer or on generally opposing sides of the gate-stacked layer.

In order to further appreciate the characteristics and technical contents of the present invention, references are hereunder made to the detailed description and appended drawings in relation with the present invention. However, the descriptions and appended drawings are shown solely for exemplary purposes, with no intention that they be used to restrict the scope of the present invention.

### BRIEF DESCRIPTION OF THE DRAWINGS

FIG. 1 is a cross-sectional diagram of the traditional planar transistor.

FIG. 2 is a cross-sectional diagram (1) of a step of the manufacturing method according to the present invention;

FIG. 3 is a cross-sectional diagram (2) of a step of the manufacturing method according to the present invention;

FIG. 4 is a cross-sectional diagram (3) of a step of the manufacturing method according to the present invention;

FIG. 5 is a cross-sectional diagrams (4) and of the manufacturing method according to the present invention;

FIG. 6 is a cross-sectional diagram (6) of the manufacturing method according to the present invention;

FIG. 7 is a cross-sectional diagram (7) of the manufacturing method according to the present invention;

FIG. 8 is a cross-sectional diagram (8) of the manufacturing method according to the present invention;

FIG. 9 is a cross-sectional diagram (9) of the manufacturing method according to the present invention;

FIG. 10 is a cross-sectional diagram (10) of the manufacturing method according to the present invention;

FIG. 11 is a cross-sectional diagram of the vertical transistor according to the first embodiment of the present invention;

FIG. 12 is a cross-sectional diagram of the vertical transistor according to the second embodiment of the present invention;

FIG. 13 is a cross-sectional diagram of the vertical transistor according to the third embodiment of the present invention; and

FIG. 14 is a cross-sectional diagram of the vertical transistor according to the fourth embodiment of the present invention.

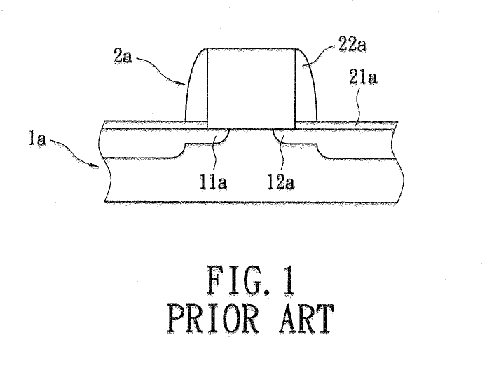

### DETAILED DESCRIPTION OF THE PREFERRED EMBODIMENTS

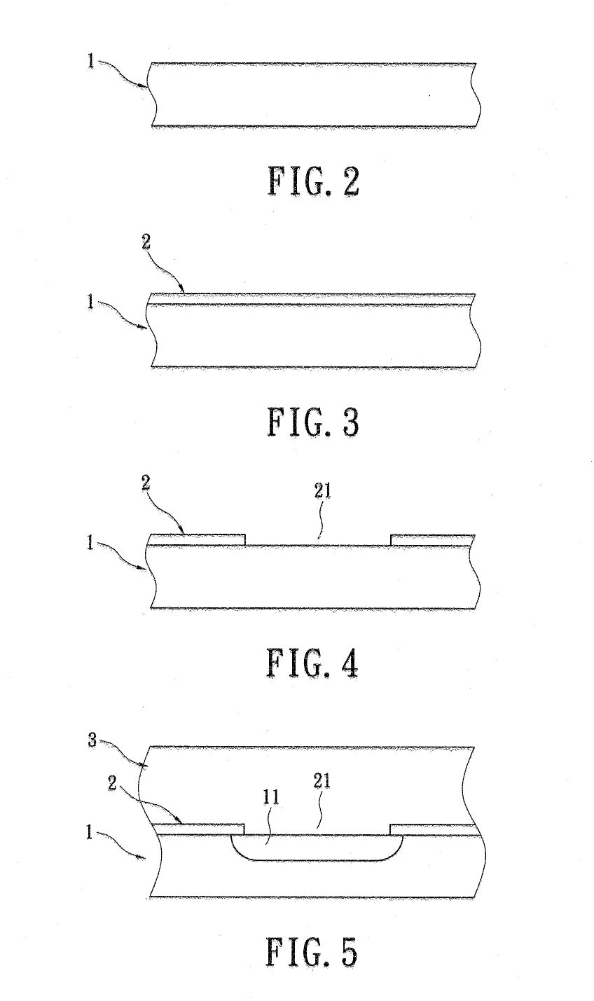

Refer now to FIGS. 2 to 10, which show the steps of the manufacturing method of a vertical transistor. The vertical transistor manufactured by the method of the present invention can be applied to dynamic random access memory (DRAM). Please refer to FIG. 2; the step (1) is providing a substrate 1, for example, the substrate 1 may be a semiconductor wafer of silicon material.

Please refer to FIG. 3; the step (2) is forming a bottom-oxide layer 2 on the substrate 1. In the embodiment, the bottom-oxide layer 2 is a silicon oxide which may be formed by a thermal oxidation method.

Please refer to FIG. 4; the step (3) is defining the pattern of the gate recess 21 on the bottom-oxide layer 2 via lithography process and then etching the defined pattern to form a gate recess 21. In other words, the gate recess 21 is concavely formed in the bottom-oxide layer 2.

Please refer to FIG. 5; steps (4) and (5) are shown as follows: The donor ions are implanted in the upper part of the substrate 1 corresponding to the gate recess 21 so that the first doped area(s) 11 is formed. The formed first doped area(s) 11 can be defined as the source or the drain of the transistor. Thereafter, an epitaxial silicon layer 3 is formed on the bottom-oxide layer 2 and gate recess 21. The bottom of the epitaxial silicon layer 3 contacts the first doped area 11 electrically. Furthermore, the surfaces of the bottom-oxide layer 2 and gate recess 21 is etched to smooth the surfaces before forming the epitaxial silicon layer 3.

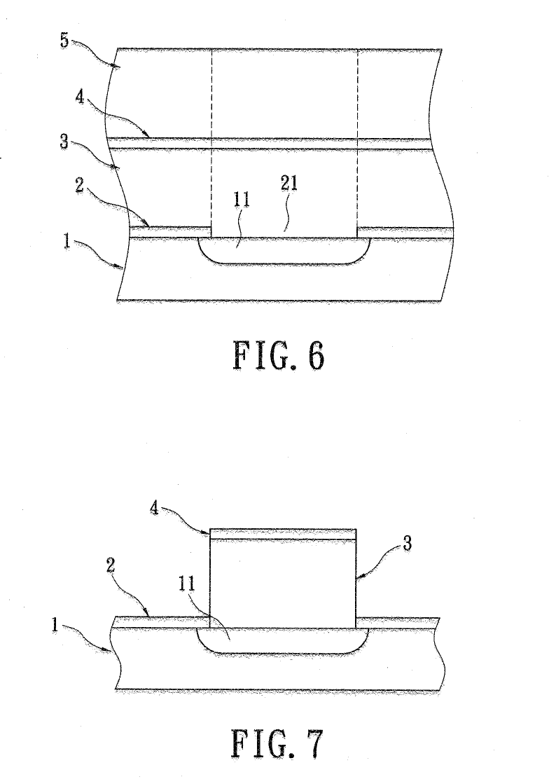

Please refer to FIG. 6; the step (6) is forming an insulating oxide layer 4 on the epitaxial silicon layer 3 so as to insulate the epitaxial silicon layer 3. Then, an insulating nitride layer 5 is formed on the insulating oxide layer 4. In the embodiment, the insulating nitride layer 5 may be used as a hard-mask which is applied to protect the transistor body. Next, a pattern of the transistor body (i.e., the broken line in FIG. 6) is defined on the insulating nitride layer 5 by lithograph process.

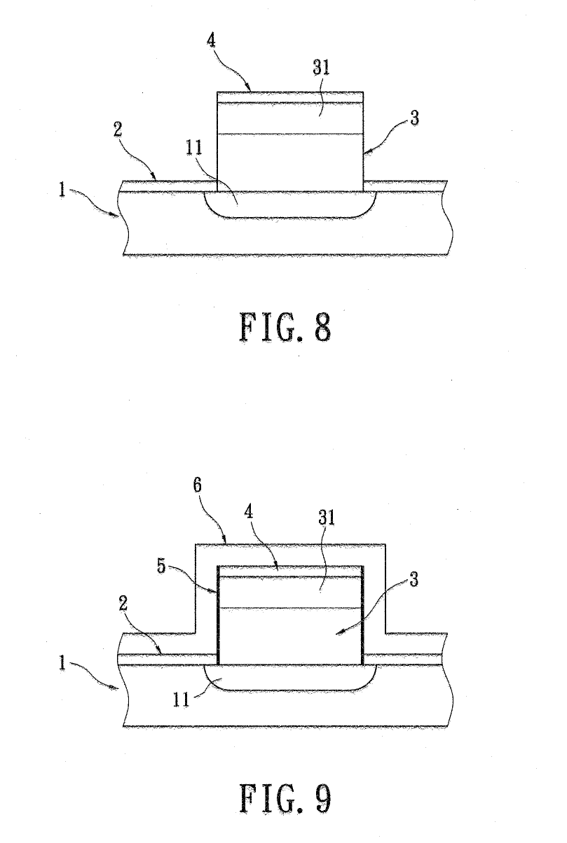

Please refer to FIG. 8; the step (8) is etching the insulating nitride layer 5, insulating oxide layer 4 and epitaxial silicon layer 3 except the parts of the insulating nitride layer 5, insulating oxide layer 4 and epitaxial silicon layer 3 in the defined pattern of transistor body (as shown in FIG. 6) and then etching and removing the remained insulating nitride layer 5 (as shown in FIG. 7). Thereafter, the insulating oxide layer 4 and epitaxial silicon layer 3 of the defined structure of the transistor body.

Please refer to FIGS. 6 and 7; the step (7) is implanting donor ions in the upper part of the epitaxial silicon layer 3 so that the second doped area(s) 31 is formed. The formed second doped area(s) 31 can be defined as the source or the drain of the transistor. In other words, when the first doped area 11 defines a drain of the vertical transistor and the second doped area 31 defines a source of the vertical transistor, or when the first doped area 11 defines a source of the vertical transistor and the second doped area 31 defines a drain of the vertical transistor. A channel is formed between the second doped area 31 and the first doped area 11 and the channel provides a path for electron(s). The length and the width of the channel make important roles for the efficiency of the transistor.

Please refer to FIG. 9; the step (9) is forming a gate-oxide film 5 respectively on two opposite sides of the epitaxial silicon layer 3 by a thermal oxidation method. Then, a gate-stacked layer 6 is formed on the insulating oxide layer 4, the gate-oxide film 5 and bottom-oxide layer 2. In the embodiment, the gate-stacked layer 6 is conductive material, which can be poly-silicon or metal.

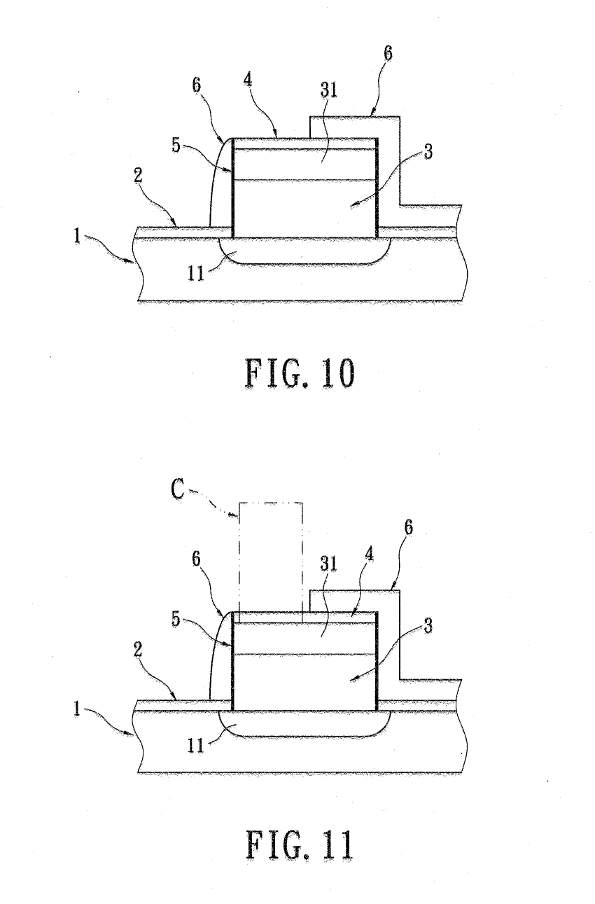

Please refer to FIG. 10; the step (10) is defining a pattern on the gate-stacked layer 6 by lithograph process so as to remove the gate-stacked layer 6 except the gate-stacked layer 6 in the defined pattern. In the embodiment, the half top of the insulating oxide layer 4 is exposed after etching/removing the gate-stacked layer partially. Thereafter, the gate/transistor body has been formed.

Please refer to FIG. 11; a capacitor C can be formed on the exposed half top of the insulating oxide layer 4 and is connected to the second doped area 31 of the epitaxial silicon layer 3 through the insulating oxide layer 4.

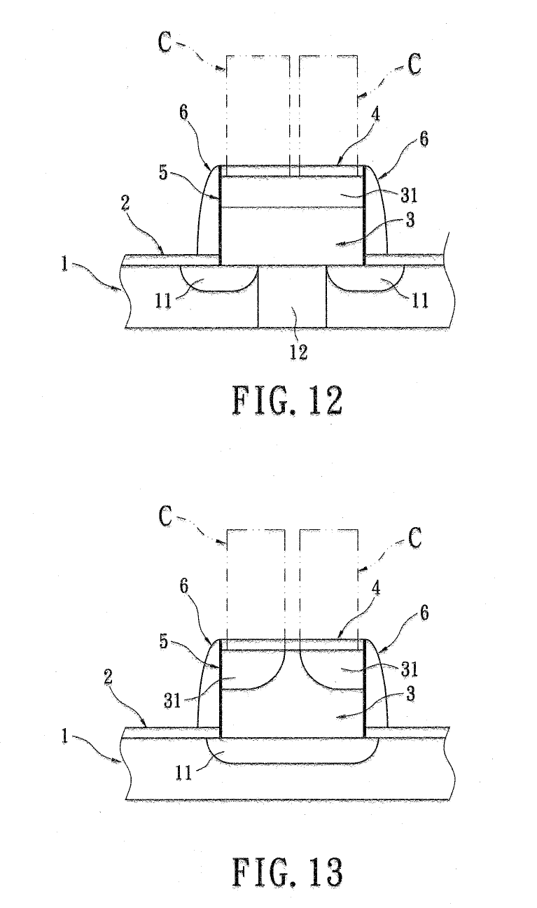

As shown in FIG. 12, another embodiment is shown. The difference between FIGS. 11 and 12 is that a shallow trench isolation 12 (STI) is further formed between the two first doped areas 11 in the step of forming the first doped areas 11 in the substrate 1. The shallow trench isolation 12 is used to isolate the two first doped areas 11. Two channels (not shown) are defined between the first doped area 11 and the second doped area 31 so that the lateral area of the transistor is reduced. Then, the portion of the gate-stacked layer 6 is etched to expose the top of the insulating oxide layer 4 entirely. Therefore, the insulating oxide layer 4 can has two capacitors C on the top thereof corresponding to the two second doped areas 31 and each capacitor C is connected to the corresponding second doped area 31 of the epitaxial silicon layer 3 through the insulating oxide layer 4. Thereafter, the remaining gate-stacked layer 6 covers on the insulating nitride layer 5 and bottom-oxide layer 2.

FIG. 13 presents another embodiment. The difference between FIGS. 11 and 13 is that the upper part of the epitaxial silicon layer 3 has two separated second doped areas 31 and one channel (not shown) is defined between each of second doped area 31 and the first doped area 11.

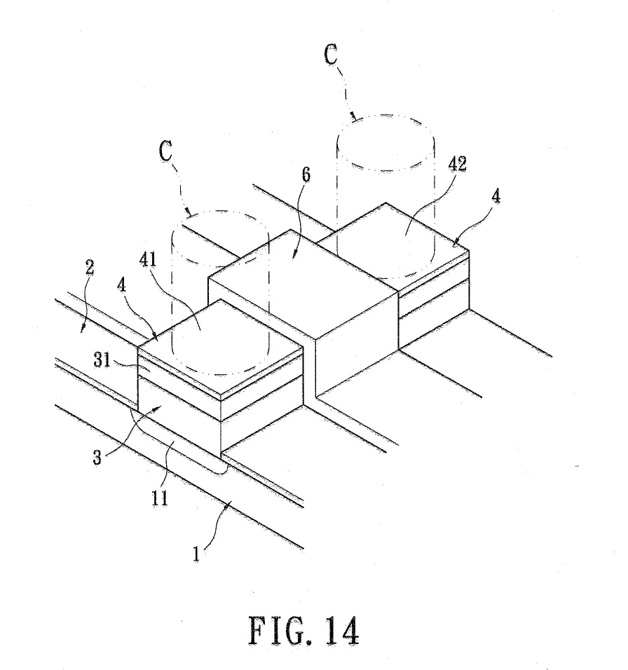

As shown in FIG. 14, another embodiment is shown. The difference between FIGS. 11 and 14 is that the gate-stacked layer 6 is partially removed by lithography and etching processes so that a first capacitor area 41 and a second capacitor area 42 are formed on the exposed insulating oxide layer 4. The remaining gate-stacked layer 6 has a strip shape, and the first capacitor area 41 and the second capacitor area 42 are formed on the front and the rear sides of the remaining gate-stacked layer 6. Therefore, two capacitors C can be formed on the first capacitor area 41 and the second capacitor area 42.

Accordingly, a vertical transistor is manufactured in the present invention and the vertical transistor has a substrate 1, bottom-oxide layer 2, epitaxial silicon layer 3, insulating oxide layer 4, gate-oxide film 5 and gate-stacked layer 6. The structure of the vertical transistor may be referenced in the above-mentioned description.

In summary of aforementioned descriptions, the present invention can provide the following advantages:

1. the source, the gate/transistor body and the drain of the transistor are vertically defined so that the lateral area of the transistor can be reduced, the integration and the performance of the semiconductor is improved;

2. the capacitor can be selectively disposed on one side of the gate-stacked layer (as shown in FIG. 11), on two sides of the gate-stacked layer (as shown in FIG. 12), or on the front and rear sides of the gate-stacked layer (as shown in FIG. 14) by etching the gate-stacked layer partially.

The text set forth previously hereinbefore illustrates, simply, the preferred embodiments of the present invention, rather than intending to restrict the scope of the present invention claimed to be legally protected. All effectively equivalent changes made by using the contents of the present disclosure and appended drawings thereof are included within the scope of the present invention delineated by the following claims.

What is claimed is:

1. A vertical transistor, comprising:
a substrate;
a bottom-oxide layer disposed on the substrate, the bottom-oxide layer having a gate recess concavely formed therein, the substrate having at least one first doped area in a upper part thereof corresponding to the gate recess;
an epitaxial silicon layer formed on the gate recess, the epitaxial silicon layer having at least one second doped area in a upper part thereof;
an insulating oxide layer disposed on the epitaxial silicon layer;
two gate-oxide films, respectively formed on two opposite sides of the epitaxial silicon layer; and
a gate-stacked layer formed on the two gate-oxide layers and the bottom-oxide layer.

2. The vertical transistor according to claim 1, wherein the first doped area defines a drain of the vertical transistor and the second doped area defines a source of the vertical transistor.

3. The vertical transistor according to claim 1, wherein the first doped area defines a source of the vertical transistor and the second doped area defines a drain of the vertical transistor.

4. The vertical transistor according to claim 1, wherein the gate-stacked layer is a poly silicon layer.

5. The vertical transistor according to claim 1, wherein the substrate further has another first doped area in the upper part thereof, and a shallow trench isolation is formed between the two first doped areas.

6. The vertical transistor according to claim 1, wherein the gate-stacked layer is further formed on the insulating oxide layer.

7. A manufacturing method of a vertical transistor, comprising steps of:
providing a substrate;
forming a bottom-oxide layer on the substrate;
etching a part of the bottom-oxide layer via lithography processes to form a gate recess on the bottom-oxide layer;
forming at least one first doped area in a upper part of the substrate corresponding to the gate recess;
depositing an epitaxial silicon layer on the gate recess and the bottom-oxide layer;
forming an insulating oxide layer on the epitaxial silicon layer, and then forming an insulating nitride layer on the insulating oxide layer;
removing a part of the insulating nitride layer, a part of insulating oxide layer and a part of epitaxial silicon layer via lithography process;
forming at least one second doped area in a upper part of the epitaxial silicon layer;
forming a gate-oxide film respectively on two opposite sides of the epitaxial silicon layer, and forming a gate-stacked layer on the insulating oxide layer, the gate-oxide film and bottom-oxide layer; and
etching a part of the gate-stacked layer via lithography processes.

8. The manufacturing method according to claim 7, further comprising a step of cleaning surfaces of the bottom-oxide layer and the gate recess, before the step of depositing an epitaxial silicon layer on the gate recess and the bottom-oxide layer.

9. The manufacturing method according to claim 7, wherein the first and the second doped areas are formed by an ion implanting process.

10. The manufacturing method according to claim 7, further comprising a step of forming a shallow trench isolation between the first doped areas in the step of forming at least one first doped area in the substrate.

11. The manufacturing method according to claim 7, wherein a half top of the insulating oxide layer is exposed in the step of etching a part of the gate-stacked layer.

12. The manufacturing method according to claim 7, wherein a top of the insulating oxide layer is exposed in the step of etching a part of the gate-stacked layer when the upper part of the epitaxial silicon layer has two second doped areas, and the etched gate-stacked layer is located on the gate-oxide film and the bottom-oxide layer.

13. The manufacturing method according to claim 7, wherein a top of the insulating oxide layer is exposed in the step of etching a part of the gate-stacked layer to form a first capacitor area and a second capacitor area, and the first capacitor area and the second capacitor area are respectively located on a front side and a rear side of the etched gate-stacked layer.

14. The manufacturing method according to claim 7, further comprising a step of etching and removing the insulating nitride layer after the step of removing a part of the insulating nitride layer, a part of insulating oxide layer and a part of epitaxial silicon layer.
